(19) United States
(12) Patent Application Publication
(10) Pub. No.: US 2006/0189028 A1
(43) Pub. Date: Aug. 24, 2006

(54) Wafer having alternating design structure and method for manufacturing semiconductor package using the same

(76) Inventor: Soo-Sang Yoon, Anyang-City Kyunggi-do (KR)

Correspondence Address: IPLA P.A., 3580 WILSHIRE BLVD., 17TH FLOOR, LOS ANGELES, CA, 90010, US

(21) Appl. No.: 10/552,333

(22) PCT Filed: Mar. 19, 2004
(86) PCT No.: PCT/KR04/00607

§ 371 Date: Oct. 7, 2005

(30) Foreign Application Priority Data
Apr. 10, 2003 (KR) 10-2003-0022723

(51) Int. Cl. H01L 21/50; H01L 23/02

(52) U.S. Cl. 438/106; 257/678

(57) ABSTRACT

The present invention relates to a wafer having an alternating design structure and a method for manufacturing a semiconductor package using the wafer. The present invention is conceived to solve all the aforementioned problems associated with the related art wafer having the lattice design arrangement and method for manufacturing a semiconductor package using the wafer. According to the present invention, the number of dies per wafer can be maximized (6 to 8 % of dies per wafer can be further produced) as compared to the conventional lattice design arrangement to allow the manufacturing costs of dies to be lowered by designing the wafer to have an alternating arrangement design structure. Further, the time taken to inspect dies can be remarkably reduced through the improvement in efficiency of a die tester by allowing the die to be inspected using a carrier when manufacturing the semiconductor package. In addition, the manufacturing process can be simplified by omitting an inking process for indexing reject dies, which has been essentially performed in the related art semiconductor package manufacturing process. Furthermore, the productivity improvement and in-line automation can be achieved by mounting a carrier, thereby contributing to reduction in price of the semiconductor manufacturing equipment.

### TECHNICAL FIELD

The present invention relates to a wafer having an alternating design structure and a method for manufacturing a semiconductor package using the wafer.

### BACKGROUND ART

As shown in FIGS. 1a to 1d, a wafer for use in manufacturing a semiconductor package is generally designed in the form of a lattice so that only a sawing process can be easily performed, in consideration of work efficiency in the manufacturing process, when designing a plurality of semiconductor chips (hereinafter, referred to as “die”) arranged on a circular wafer having a predetermined size.

Of course, it is preferable that the die be designed in the form of a lattice in consideration of workability of a linear sawing process. However, it is inevitable that the number of effective dies, which can be contained in a disk-shaped wafer, is limited because the wafer is constructed in the form of a disk.

Therefore, even though the dies are optimally arranged within the range of a lattice shape, the number of effective dies 101 are merely 259 in FIG. 1a, 258 in FIG. 1b, 264 in FIG. 1c, or 254 in FIG. 1d. Under such circumstances, the maximized number of the effective dies can be at most 264.

Furthermore, as shown in FIG. 2, a method for performing the inspection for directly searching reject dies in every predetermined region in a state where the individual dies 101 are attached to an adhesive sheet (not shown) after the sawing process has been completed was used to manufacture a semiconductor package using the wafer having such a lattice arrangement. Therefore, since all the things including ineffective dies (materials which are positioned near the circumference of the wafer and can also be discriminated as not being the dies by the naked eye) should be inspected (for example, when the inspection is performed for each 4×4 region (including 16 dies), only one effective die may be sometimes inspected), there is a problem in that it takes long time to perform the inspection. In addition, there is another problem in that an inking process of putting a specific mark on a surface of a reject die should be added to discriminate the reject dies searched in the inspection process, thereby causing the manufacturing process to be further complicated.

### DISCLOSURE OF THE INVENTION

The present invention is conceived to solve all the aforementioned problems associated with the related art wafer having the lattice design arrangement and method for manufacturing a semiconductor package using the wafer. Accordingly, an object of the present invention is to maximize the number of dies per wafer (further generating 6 to 8% of dies) as compared to the conventional lattice design arrangement to allow the manufacturing costs of dies to be lowered by designing the wafer to have an alternating arrangement design structure. Another object of the present invention is to remarkably reduce the time taken to inspect dies through the improvement in efficiency of a die tester by allowing the die to be inspected using a carrier when manufacturing the semiconductor package. In addition, a further object of the present invention is to allow the manufacturing process to be simplified by omitting an inking process for indexing reject dies, which has been essentially performed in the related art semiconductor package manufacturing process. More specifically, a still further object of the present invention is to achieve the productivity improvement and in-line automation by mounting a carrier with dies for the handling of the dies by the carrier, thereby contributing to reduction in price of the semiconductor manufacturing equipment.

The wafer having an alternating design structure of the present invention has the following structural characteristics.

According to an aspect of the present invention, there is provided a wafer wherein a plurality of strips having a die arrangement structure in which their dies are designed to have an equal width are alternately arranged from the center of the wafer.

Preferably, first strips that are positioned closest to the center of the wafer adjoin each other to be symmetric with each other, and the other strips arranged sequentially on the outside of the first strips are alternately staggered.

More preferably, the strips comprises the first strips which have a die arrangement structure in which their dies are designed to have an equal width; second strips which adjoin the first strips to be symmetric with each other, are arranged in at least one row such that their dies are designed to have an equal width, and are configured in such a manner that their dies are staggered with the respective dies of the first strips; third strips that adjoin the second strips to be symmetric with each other, are arranged in at least one row such that their dies are designed to have an equal width, and are configured in such a manner that their dies are aligned with those of the first strips but staggered with those of the second strips; fourth strips that adjoin the third strips to be symmetric with each other, are arranged in at least one row such that their dies are designed to have an equal width, and are configured in such a manner that their dies are aligned with those of the second strips but staggered with those of the first and third strips; fifth strips that adjoin the fourth strips to be symmetric with each other, are arranged in at least one row such that their dies are designed to have an equal width, and are configured in such a manner that their dies are aligned with those of the first and third strips but staggered with those of the second and fourth strips; sixth strips that adjoin the fifth strips to be symmetric with each other, are arranged in at least one row such that their dies are designed to have an equal width, and are configured in such a manner that their dies are aligned with those of the second and fourth strips but staggered with those of the first, third and fifth strips; seventh strips that adjoin the sixth strips to be symmetric with each other, are arranged in at least one row such that their dies are designed to have an equal width, and are configured in such a manner that their dies are aligned with those of the first, third and fifth strips but staggered with those of the second, fourth and sixth strips; eighth strips that adjoin the seventh strips to be symmetric with each other, are arranged in at least one row such that their dies are designed to have an equal width, and are configured in such a manner that their dies are aligned with those of the second, fourth and sixth strips but staggered with those of the first, third, fifth and seventh strips; and ninth strips that adjoin the eighth strips to be symmetric with each other, are arranged in at least one row such that their dies are designed to have an equal width, and are configured in such a manner that their dies are aligned with those of the first, third, fifth and seventh strips but staggered with those of the second, fourth, sixth and eighth strips.

Furthermore, the first strips may be arranged in two rows to be symmetric with each other with respect to the center of the wafer and configured in such a manner that the center of the wafer is located between two specific dies thereof.

According to another aspect of the present invention, there is provided a method for manufacturing a semiconductor package using the wafer of the present invention, wherein singulated dies are mounted on a carrier so that a number of die testing works can be implemented at one time. Therefore, the time taken to inspect the dies can be remarkably reduced through the improvement in efficiency of a die tester and the inking process of indexing reject dies can also be omitted. Accordingly, there are advantages in that simplification of the manufacturing process, improvement in productivity and reduction in the manufacturing costs can be achieved.

### BRIEF DESCRIPTION OF THE DRAWINGS

The above objects, features and advantages of the present invention will become more apparent from the following detailed description when taken in conjunction with the accompanying drawings, in which:

FIGS. 1a to 1d are views illustrating examples of a wafer having the conventional lattice arrangement design structure;

FIG. 2 is a view illustrating the process of manufacturing a semiconductor package using the conventional wafer;

FIG. 3 is a view illustrating an example of a wafer having a preferred alternating arrangement design structure according to the present invention;

FIG. 4 is a view illustrating an example of a state of the wafer where it has been first sawed along a horizontal line for die design according to the present invention;

FIG. 5 is a view illustrating an example of the wafer in which the lattice arrangement design structure has been formed by moving alternately arranged strips among the first sawed strips to be vertically aligned along a vertical line for die design according to the present invention;

FIG. 6 is a view illustrating an example of a state of the wafer where the wafer aligned in the form of a lattice has been secondarily sawed along the vertical line for die design according to the present invention;

FIG. 7 is a flowchart schematically illustrating the process of manufacturing a semiconductor package using the wafer having the alternating arrangement design structure according to the present invention;.

FIG. 8 is a view illustrating an example of a waffle-shaped carrier on which dies singulated from the completely sawed wafer are mounted according to the present invention;

FIG. 9 is a view illustrating how to inspect a reject die using the carrier with the dies mounted thereon according to the present invention;

FIG. 10 is a view illustrating how to remove the reject dies from the inspected carrier by using a sorting picker according to the present invention; and

FIG. 11 is a view illustrating how to supply dies to a die bonder by using the carrier according to the present invention.

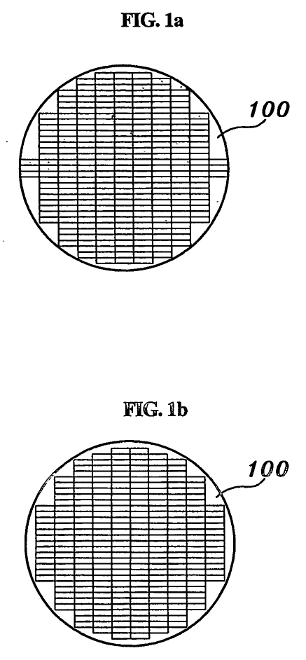

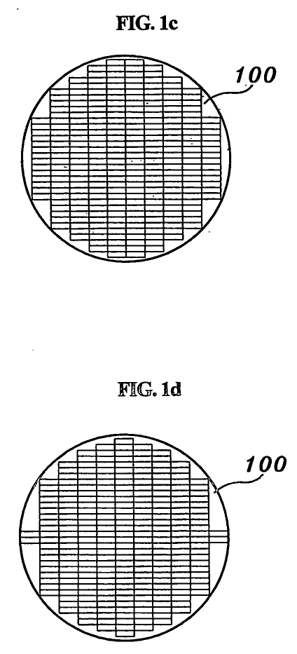

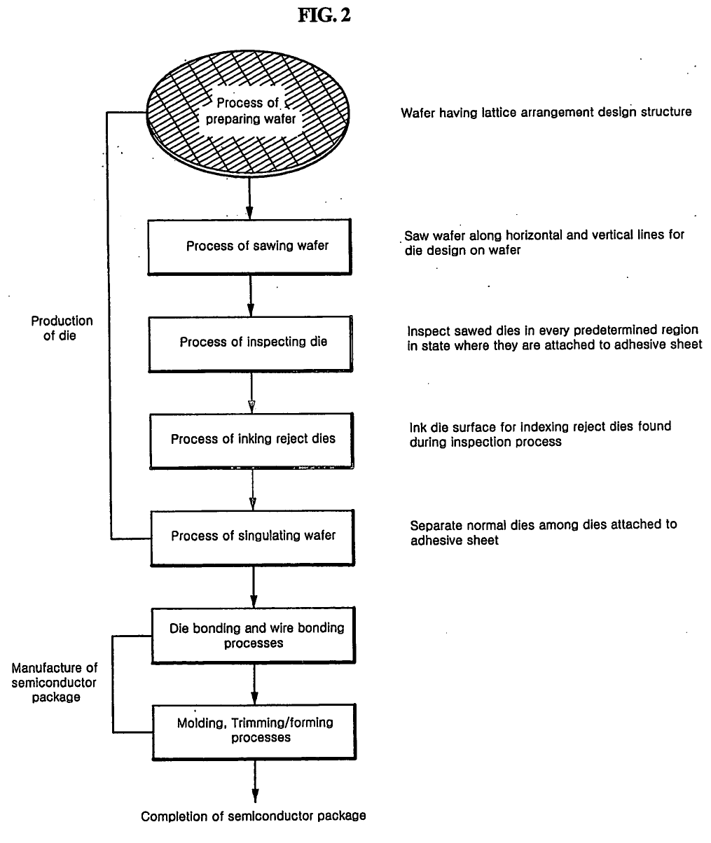

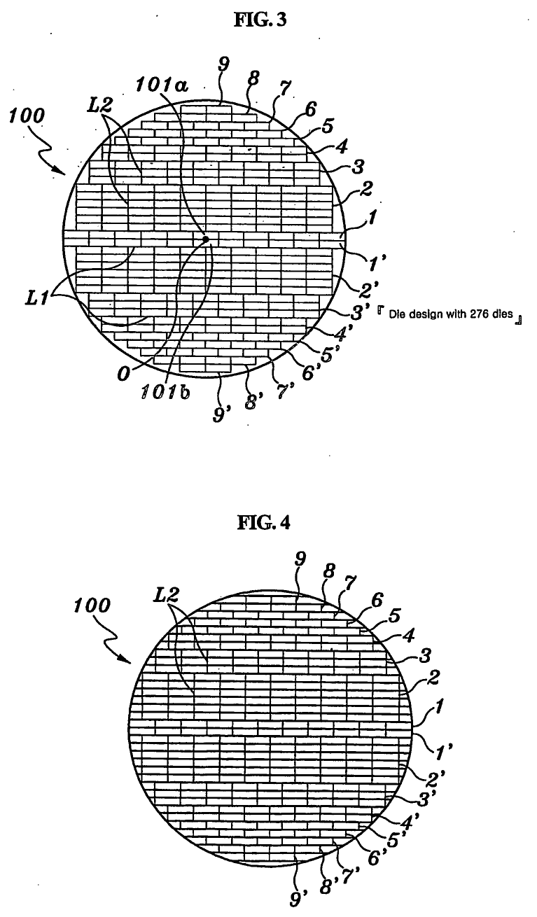

### BEST MODE FOR CARRYING OUT THE INVENTION

A preferred embodiment of the present invention will be hereinafter described with reference to the accompanying drawings.

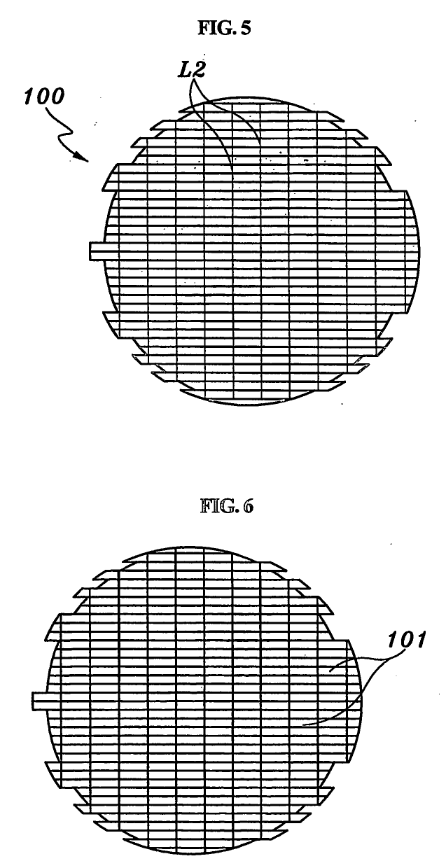

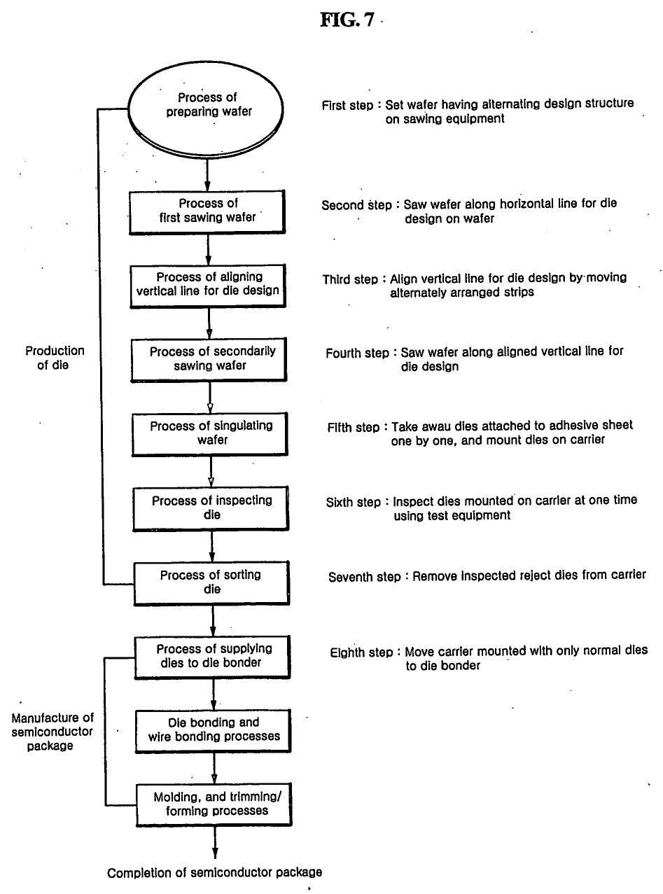

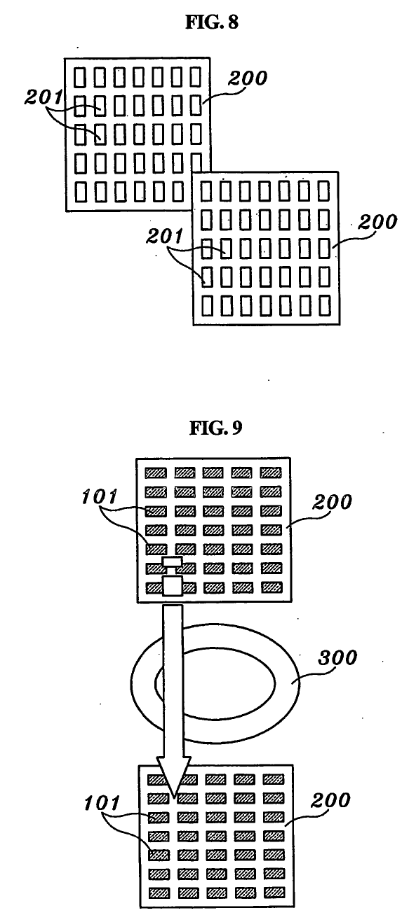

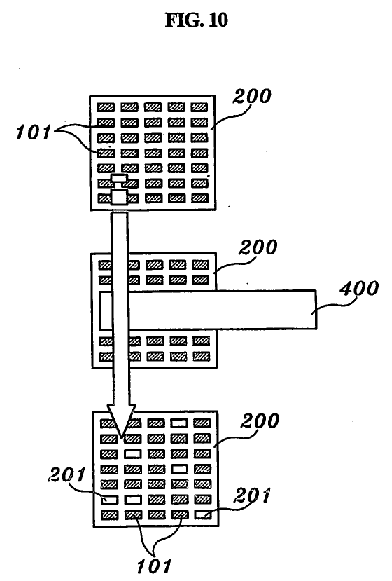

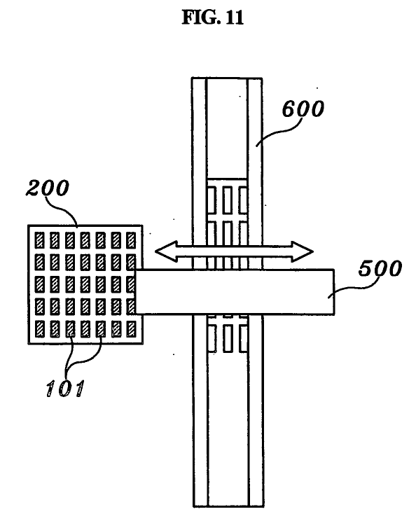

FIG. 3 is a view illustrating an example of a wafer having a preferred alternating arrangement design structure according to the present invention; FIG. 4 is a view illustrating an example of a state of the wafer where it has been first sawed along a horizontal line for die design according to the present invention; FIG. 5 is a view illustrating an example of the wafer in which the lattice arrangement design structure has been formed by moving alternately arranged strips among the first sawed strips to be vertically aligned along a vertical line for die design according to the present invention; FIG. 6 is a view illustrating an example of a state of the wafer where the wafer aligned in the form of a lattice has been secondarily sawed along the vertical line for die design according to the present invention; FIG. 7 is a flowchart schematically illustrating the process of manufacturing a semiconductor package using the wafer having the alternating arrangement design structure according to the present invention; FIG. 8 is a view illustrating an example of a waffle-shaped carrier on which dies singulated from the completely sawed wafer are mounted according to the present invention; FIG. 9 is a view illustrating how to inspect a reject die using the carrier with the dies mounted thereon according to the present invention; FIG. 10 is a view illustrating how to remove the reject dies from the inspected carrier by using a sorting picker according to the present invention; and FIG. 11 is a view illustrating how to supply dies to a die bonder by using the carrier according to the present invention.

Referring to FIG. 3, a wafer 100 of the present invention has such a structure that dies 101 are arranged on a strip basis to have an alternating arrangement design structure so that the number of the dies 101 per wafer 100 can be maximized. That is, a plurality of strips 1 to 9 and 1′ to 9′, which adjoin one another in a symmetric manner with respect to a center point 0 of the wafer 100 and constitutes a die arrangement structure in which dies are designed to have an equal width, are arranged alternately with one another. More specifically, the strips 2 to 9 and 2′ to 9′ that are arranged sequentially from the first strips 1 and 1′ positioned closest to the center point of the wafer 100 are alternately staggered with one another.

The die design arrangement structure that is optimized for the wafer 100 of the present invention will be now described in detail.

The first strips 1 and 1′ having a die arrangement structure in which their dies are designed to have an equal width are arranged horizontally side by side in two rows to be symmetric with each other with respect to the center point 0 of the wafer 100. In other words, the first strips 1 and 1′ are configured in such a manner that the center point 0 of the wafer 100 is located between two specific dies 101a and 101b that constitute the first strips 1 and 1′, respectively.

Then, the second strips 2 and 2′ having a die arrangement structure in which their dies are designed to have an equal width are arranged in at least one row such that the second strips adjoin the first strips 1 and 1′ to be symmetric with each other (in a vertical direction as shown in FIG. 3). At this time, the second strips 2 and 2′ are configured in such a manner that the dies of the strips 2 and 2′ are staggered with the respective dies 101 of the first strips 1 and 1′. It is shown in FIG. 3 that the second strips have a six-row strip structure.

Further, the third strips 3 and 3′ having a die arrangement structure in which their dies are designed to have an equal width are arranged in at least one row such that the third strips adjoin the second strips 2 and 2′ to be symmetric with each other. Here, the third strips 3 and 3′ are configured in such a manner that their dies are aligned with those of the first strips 1 and 1′ but are staggered with those of the second strips 2 and 2′. It is shown in FIG. 3 that the third strips have a three-row strip structure.

Further, the fourth strips 4 and 4′ having a die arrangement structure in which their dies are designed to have an equal width are arranged in at least one row-such that the fourth strips adjoin the third strips 3 and 3′ to be symmetric with each other. Here, the fourth strips 4 and 4′ are configured in such a manner that their dies are aligned with those of the second strips 2 and 2′ but are staggered with those of the first strips 1 and 1′ and the third strips 3 and 3′. It is shown in FIG. 3 that the fourth strips have a two-row strip structure.

Further, the fifth strips 5 and 5′ having a die arrangement structure in which their dies are designed to have an equal width are arranged in at least one row such that the fifth strips adjoin the fourth strips 4 and 4′ to be symmetric with each other. Here, the fifth strips 5 and 5′ are configured in such a manner that their dies are aligned with those of the first strips 1 and 1′ and the third strips 3 and 3′ but are staggered with those of the second strips 2 and 2′ and the fourth strips 4 and 4′. It is shown in FIG. 3 that the fifth strips have a one-row strip structure.

Further, the sixth strips 6 and 6′ having a die arrangement structure in which their dies are designed to have an equal width are arranged in at least one row such that the sixth strips adjoin the fifth strips 5 and 5′ to be symmetric with each other. Here, the sixth strips 6 and 6′ are configured in such a manner that their dies are aligned with those of the second strips 2 and 2′ and the fourth strips 4 and 4′ but are staggered with those of the first strips 1 and 1′, the third strips 3 and 3′ and the fifth strips 5 and 5′. It is shown in FIG. 3 that the sixth strips have a one-row strip structure.

Further, the seventh strips 7 and 7′ having a die arrangement structure in which their dies are designed to have an equal width are arranged in at least one row such that the seventh strips adjoin the sixth strips 6 and 6′ to be symmetric with each other. Here, the seventh strips 7 and 7′ are configured in such a manner that their dies are aligned with those of the first strips 1 and 2′, the third strips 3 and 3′ and the fifth strips 5 and 5′ but are staggered with those of the second strips 2 and 2′, the fourth strips 4 and 4′ and the sixth strips 6 and 6′. It is shown in FIG. 3 that the seventh strips have a one-row strip structure.

Further, the eighth strips 8 and 8′ having a die arrangement structure in which their dies are designed to have an equal width are arranged in at least one row such that the eighth strips adjoin the seventh strips 7 and 7′ to be symmetric with each other. Here, the eighth strips 8 and 8′ are configured in such a manner that their dies are aligned with those of the second strips 2 and 2′, the fourth strips 4 and 4′ and the sixth strips 6 and 6′ but are staggered with those of the first strips 1 and 1′, the third strips 3 and 3′, the fifth strips 5 and 5′ and the seventh strips 7 and 7′. It is shown in FIG. 3 that the eighth strips have a one-row strip structure.

Further, the ninth strips 9 and 9′ having a die arrangement structure in which their dies are designed to have an equal width are arranged in at least one row such that the ninth strips adjoin the eighth strips 8 and 8′ to be symmetric with each other. Here, the ninth strips 9 and 9′ are configured in such a manner that their dies are aligned with those of the first strips 1 and 1′, the third strips 3 and 3′, the fifth strips 5 and 5′ and the seventh strips 7 and 7′ but are staggered with those of the second strips 2 and 2′, the fourth strips 4 and 4′, the sixth strips 6 and 6′ and the seventh strips 7 and 7′. It is shown in FIG. 3 that the ninth strips have a one-row strip structure.

As described above, according to the present invention, the number of the dies 101 per wafer 100 can be maximized by designing the die arrangement in each strip in such a manner that the strips are alternately arranged.

Hereinafter, a method for manufacturing a semiconductor package using the wafer having such an alternating arrangement design structure will be described in detail.

<First step: Process of preparing wafer>

A wafer 100 having an alternating design structure is set on sawing equipment (not shown).

<Second step: Process of first sawing wafer>

Precise sawing process is performed along a horizontal line L1 for die design on the wafer 100. Thus, the wafer 100 is in a state where it is cut along the horizontal line L1 for die design as shown-in FIG. 4.

<Third step: Process of aligning vertical lines for die design>

The alternately arranged second, fourth, sixth and eighth strips 2 and 2′, 4 and 4′, 6 and 6′, and 8 and 8′ are taken away from the first sawed wafer 100 by means of a vacuum holder (not shown), and moved horizontally (by a distance equal to a half of the die length) and attached again to an adhesive sheet (not shown) so that the vertical lines L2 for die design of the first, third, fifth, seventh and ninth strips 1 and 1′, 3 and 3′, 5 and 5′, 7 and 7′, and 9 and 9′ are exactly aligned with one another. Thus, the wafer 100 is obtained in the form of the lattice arrangement as shown in FIG. 5.

In the meantime, to enhance work efficiency, the first sawed wafers 100 that have passed through the second step (the process of first sawing the wafer) may be moved to a predetermined location so that the third step (the process of aligning the vertical lines for die design) can be separately performed at one time.

<Fourth step: Process of secondarily sawing wafer>

Precise sawing process is performed along the vertical line L2 of the wafer 100 arranged in the form of a lattice. Thus, the wafer 100 is in a state where it is also cut along the vertical line L2 for die design as shown in FIG. 6. That is, the respective dies 101 are attached to the adhesive sheet in a state where they are separated from each other.

At this time, to improve the work accuracy, a process of inspecting whether the vertical line L2 for die design has been correctly aligned may be added prior to the fourth step (the process of secondarily sawing the wafer).

<Fifth step: Process of singulating wafer>

As shown in FIG. 8, the dies 101 that have been attached apiece to the adhesive sheet are taken away one by one using a die picker 500 and then sequentially mounted on pockets 201 of a waffle-shaped carrier 200.

In the meantime, to enhance work efficiency, the secondarily sawed wafers 100 that have passed through the fourth step (the process of secondarily sawing the wafer) may be moved to a predetermined location so that the fifth step (the process of singulating the wafer) can be separately performed at one time.

<Sixth step: Process of inspecting die>

As shown in FIG. 9, the carrier 200 on which the dies 101 are mounted is passed over test equipment 300 so that reject dies can be found by only a single inspection.

<Seventh step: Process of sorting die>

As shown in FIG. 10, the reject dies found in the process of inspecting the die are removed from the carrier 200 by means of a sorting picker 400.

<Eighth step: Process of supplying die to die bonder>

As shown in FIG. 11, the carrier 200 mounted with only the normal dies is moved to a dir bonder 600 so that the dies 101 can be supplied to the die bonder. 600 by means of a die picker 500.

The die bonding, wire bonding, molding, trimming/forming and other essential manufacturing processes are subsequently performed, and a single semiconductor package is finally manufactured.

### INDUSTRIAL APPLICABILITY

According to the present invention, the wafer having an alternating arrangement design structure is employed. Therefore, there is an advantage in that manufacturing costs can be reduced because 6 to 8% of dies per wafer can be further produced as compared to the conventional wafer having a lattice arrangement. In addition, the dies are inspected using the carrier 200, and thus, efficiency of a die tester is also improved. Therefore, there is another advantage in that the time taken to inspect the dies 101 can be greatly reduced.

Further, according to the present invention, since an inking process of indexing the reject dies, which has been essentially performed during the conventional process of manufacturing the semiconductor package, can be omitted, the semiconductor package manufacturing process can be simplified. Moreover, since the dies 101 are mounted on the carrier 200 so that the dies 101 can be handled by the carrier 200, the productivity improvement and in-line automation can be achieved, thereby contributing to reduction in price of the semiconductor manufacturing equipment.

Furthermore, upon the manufacture of the semiconductor package according to the present invention, if the first sawed wafers 100 that have passed through the second step (the process of first sawing the wafer) are moved to a predetermined location to perform the third step (the process of aligning the vertical lines for die design), the work efficiency can be enhanced. In addition, if the secondarily sawed wafers 100 that have passed through the fourth step (the process of secondarily sawing the wafer) are moved to a predetermined location to perform the fifth step (the process of singulating the wafer), the work efficiency can also be enhanced.

Although the present invention has been described by way of example in connection with the aforementioned embodiment, the scope of the present invention should not be construed as being limited to the embodiment illustrated in the accompanying drawings.

1. A wafer, wherein a plurality of strips having a die arrangement structure in which dies are designed to have an equal width are alternately arranged from the center of the wafer.

2. The wafer as claimed in claim 1, wherein first strips positioned closest to the center of the wafer adjoin each other to be symmetric with each other, and other strips arranged sequentially on the outside of the first strips are alternately staggered.

3. The wafer as claimed in claim 1 or 2, wherein the strips comprises:
first strips which have a die arrangement structure in which their dies are designed to have an equal width;
second strips which adjoin the first strips to be symmetric with each other, are arranged in at least one row such that their dies are designed to have an equal width, and are configured in such a manner that their dies are staggered with the respective dies of the first strips;
third strips that adjoin the second strips to be symmetric with each other, are arranged in at least one row such that their dies are designed to have an equal width, and are configured in such a manner that their dies are aligned with those of the first strips but staggered with those of the second strips;
fourth strips that adjoin the third strips to be symmetric with each other, are arranged in at least one row such that their dies are designed to have an equal width, and are configured in such a manner that their dies are aligned with those of the second strips but staggered with those of the first and third strips;
fifth strips that adjoin the fourth strips to be symmetric with each other, are arranged in at least one row such that their dies are designed to have an equal width, and are configured in such a manner that their dies are aligned with those of the first and third strips but staggered with those of the second and fourth strips;
sixth strips that adjoin the fifth strips to be symmetric with each other, are arranged in at least one row such that their dies are designed to have an equal width, and are configured in such a manner that their dies are aligned with those of the second and fourth strips but staggered with those of the first, third and fifth strips;
seventh strips that adjoin the sixth strips to be symmetric with each other, are arranged in at least one row such that their dies are designed to have an equal width, and are configured in such a manner that their dies are aligned with those of the first, third and fifth strips but staggered with those of the second, fourth and sixth strips;
eighth strips that adjoin the seventh strips to be symmetric with each other, are arranged in at least one row such that their dies are designed to have an equal width, and are configured in such a manner that their dies are aligned with those of the second, fourth and sixth strips but staggered with those of the first, third, fifth and seventh strips; and
ninth strips that adjoin the eighth strips to be symmetric with each other, are arranged in at least one row such that their dies are designed to have an equal width, and are configured in such a manner that their dies are aligned with those of the first, third, fifth and seventh strips but staggered with those of the second, fourth, sixth and eighth strips.

4. The wafer as claimed in claim 3, wherein the first strips are arranged in two rows to be symmetric with each other with respect to the center of the wafer and configured in such a manner that the center of the wafer is located between two specific dies thereof.

5. A method for manufacturing a semiconductor package using a wafer having an alternating arrangement design structure, comprising the steps of:
(1) preparing to saw the wafer (100) by setting the wafer (100) on sawing equipment;
(2) performing a first precise sawing process along a horizontal line (L1) for die design on the wafer (100);
(3) taking away alternately arranged second, fourth, sixth, eighth strips (2, 2′; 4, 4′; 6, 6′; and 8, 8′) from the first sawed wafer and moving the second, fourth, sixth and eighth strips so that their vertical lines (L2) for die design are correctly aligned with those of first, third, fifth, seventh and ninth strips;
(4) performing a second precise sawing process along the vertical lines (L2) for die design of the wafer (100) arranged in the form of a lattice;
(5) singulating the dies (101) attached apiece to an adhesive sheet and mounting the dies on pockets (201) of a carrier (200) one by one;
(6) inspecting reject dies from the carrier (200) mounted with the dies (101);
(7) sorting the reject dies found during the die inspection step and removing the reject dies from the carrier (200);
(8) moving the carrier (200) mounted with only normal dies and supplying the dies (100) to a die bonder (600); and
(9) performing general die bonding process, wire bonding process, molding process and trimming/forming process.

6. The method as claimed in claim 5, wherein the first sawed wafers (100) that have passed through step (2) are moved to a predetermined location so that step (3) can be separately performed at one time.

7. The method as claimed in claim 5, wherein the secondarily sawed wafers (100) that have passed through step (4) are moved to a predetermined location so that step (5) can be separately performed at one time.
